(19) United States
(12) Patent Application Publication
(10) Pub. No.: US 2003/0043875 A1
(43) Pub. Date: Mar. 6, 2003

(54) Semiconductor laser and method of manufacturing the same

(75) Inventors: Koichi Gen-Ei, Chiba (JP); Akira Tanaka, Kanagawa (JP); Yoshiyuki Itoh, Saitama (JP); Minoru Watanabe, Tokyo (JP); Hajime Okuda, Kanagawa (JP)

Correspondence Address: HOGAN & HARTSON L.L.P., 500 S. GRAND AVENUE, SUITE 1900, LOS ANGELES, CA, 90071-2611, US

(73) Assignee: KABUSHIKI KAISHA TOSHIBA

(21) Appl. No.: 10/232,605

(22) Filed: Aug. 30, 2002

(30) Foreign Application Priority Data
Aug. 31, 2001 (JP) 2001-263620

(51) Int. Cl. H01S 5/223

(52) U.S. Cl. 372/46

(57) ABSTRACT

The present invention is directed to a semiconductor laser which is comprised of a cladding layer (103) of a fist conductivity type having a vertically uniform distribution of refractive index, an active layer (107) laid over the cladding layer of the first conductivity type, a cladding layer (108, 110) of a second conductivity type laid over the active layer, having a vertically uniform distribution of refractive index, and having ridges shaped therein, each ridge extending in parallel with a direction of laser oscillation, and a current blocking layer (113) provided on opposite flanks of each ridge. In the semiconductor laser, current of which flow is pinched by the current blocking layer is introduced into the active layer thorough the upper opening of the ridge. The cladding layers of the first and second conductivity types are respectively made of semiconductor materials having almost the same composition, and a film thickness of the cladding layer of the first conductivity type is larger than a film thickness of the cladding layer of the second conductivity type along with a height of the ridge.

### CROSS-REFERENCE TO RELATED APPLICATIONS

This application is based upon and claims the benefit of priority from the prior Japanese Patent Application No. 2001-263620, filed on Aug. 31, 2001; the entire contents of which are incorporated herein by reference.

### BACKGROUND OF THE INVENTION

The present invention relates to a semiconductor laser and a method of manufacturing the same, and more particularly, it relates to a semiconductor laser with a high optical output advantageously usable for a pickup of an optical disc-drive system, and a method of manufacturing the same.

For recent years, a wide variety of optical disc systems such as DVD (digital versatile disk), CD (compact disk), and the like have become available. Especially, demand for recordable (or rewritable) optical disc has drastically been increased. For these innovative optical disc systems, semiconductor laser of enhanced optical output is essential for accelerated writing by means of optical pickup. Above all, AlGaAs semiconductor laser used at a wavelength of 780 nm is suitable for CD-R/RW (CD-Recordable/Rewritable) system, and InGaAlP semiconductor laser used at a wavelength of 650 nm is for DVD-R, DVD-RW, DVD-RAM (random access memory) system. Demand for further enhancement of optical laser throughput has got stronger as day follows day.

FIG. 11 is a diagram showing an InGaAlP ridged real refractive index waveguide semiconductor laser that is embodied for a trial by the inventors of the present invention in the course of attempting to make the invention complete. FIG. 11 illustrates a cross-sectional structure taken along a plane parallel to a laser light emitting facet. The structure will be described below in stepwise order in accordance with its manufacturing procedure.

First, an GaAs substrate 402 of an n-type (or first-conductivity type) is superposed with an n-type InGaAlP cladding layer 403, which is further superimposed with InGaAlP MQW (multiple quantum well) active layer 407 and an InGaAlP cladding layer of a p-type (or second conductivity type).

The p-type cladding layer 408 is partially etched away so as to leave the residual area in striped pattern of vertical thickness h. After the partially raised surface structure, or ridged surface is created, an InAlP layer 409 of the n-or first-conductivity-type is deposited over shoulders and flattened top of the ridges by means of selective growth on the residual p-type cladding layer having a film thickness h, and in this way, a current blocking layer is formed. The current blocking layer 409 and the upper ridges are covered with a GaAs layer 410 of the p-type (or second conductivity type), and thus, the ridged waveguide structure is completed.

In manufacturing the semiconductor laser of such the n-type ridged structure, before creating the ridges, the crystal growth is carried out over a flat surface to produce the active layer 407 generating laser, and the cladding layers 403 an 308, respectively, and this is useful to obtain films of good crystallinity which brings about excellent properties of reproducibility and reliability.

Since InAlP for the current blocking layer 409 assumes wider band gap than InGaP and InGaAl MQW layers for the active layer 407, InAlP is a compound semiconductor material that is not only transparent to any oscillation wavelength of laser but is smaller in refractive index than InGaAlP for the cladding layers 403 and 408. Due to such nature of the composition, the InAlP current blocking layer pinches incoming current flow to the active layer, and additionally, unlike the current blocking layer of GaAs, it forces as well the laser light propagating through the waveguide in the active layer to be confined in a directional path horizontal to junctions of the active layer right below the ridges because of a differential index of refractivity without absorbing leaky rays of the laser into the cladding layer. In this way, semiconductor laser of the so-called “real refractive index waveguide structure” can be attained.

Such real refractive index semiconductor laser has features of lower threshold and high current-optical throughput efficiency, which gives increased optical throughput with reduced current. A “complex refractive index waveguide” ridged laser including GaAs for the current blocking layer allows high current to flow upon output of high power, and this leads to thermal attenuation where Joule heat diminishes optical output, which disturbs an enhancement of optical throughput.

In contrast, such thermal attenuation does not occur so often in the real refractive index waveguide laser, and the maximum prospective optical throughput is considerably higher than that which is attained by the birefringent index waveguide laser. The real refractive index waveguide laser inherently generates less heat to attain the same rate of optical output, and this nature permits the laser device to be operative at higher temperature. With such significantly improved high-temperature operation property, the real refractive index waveguide structure is suitably applied to semiconductor laser that is operative with relatively low optical output raging from 5 mW to 20 mW, and it is especially suitable for applied use for low-current energy-saving optical pickup, resulting in an enhanced margin of design and an improved producibility.

However, the ridged real refractive index waveguide laser is disadvantageous in some points as mentioned below.

Unlike the complex refractive index waveguide laser, absorption of light by the current blocking layer 409 is unlikely in the real refractive index waveguide laser. Thus, a high rate of the laser light propagating in the active layer 407 “leaks” into the p-type cladding layer 408 and the current blocking layer 409 below the current blocking layer 409, compared to the complex refractive index waveguide laser. This means the ridged real refractive index waveguide laser, when fabricated with the ridges similarly dimensioned to those in the complex refractive index waveguide laser, would have a narrowed angle θ_{∥} horizontally diverging beam relative to the junction plane.

FIG. 12 is a table having data listed regarding samples of the angles of diverging light in the real refractive index waveguide laser and the complex refractive index waveguide laser. The listed data are all obtained in the conditions as follows: The n-type cladding layer 403 and the p-type cladding layer 408 include InGaAlP composition that is represented as In_{0.5} (Ga₁₋ₓ Alₓ)_{0.5}P where Al ratio in the composition is 0.7, and a film thickness of the cladding layer ranges from 1.4 to 1.0 μm, a width WL at the bottom of each ridge ranges from 4.0 to 4.5 μm, and a thickness h of a flattened portion of the p-type cladding layer is 0.2 μm. For these predetermined values, the angles θ_{⊥} and θ_{∥} of vertically and horizontally diverging beams relative to the junction, respectively, are simulated.

Referring to FIG. 12, the angle θ_{⊥} vertically diverging beam is fixed at the same value (23°) regardless of the laser structure, for the same film thickness of the cladding layer. On the other hand, assuming that the film thickness of the cladding layer is 1.4 μm and the ridge width WL at its bottom 4.5 μm, the angle θ_{∥} of horizontally diverging beam is 8.2° in the complex refractive index waveguide laser while it is less than 8°, preferably 7.5° in the real refractive index waveguide laser.

In the semiconductor laser used for DVD-R/RW/RAM and CD-R/RW, θ_{∥} is desirably 8° or larger in relation with write pits in the optical disc in order to keep an optical coupling coefficient at a certain level or higher. The angle becomes 8.1° and falls in a range desired, as the width WL is reduced down to 4.0 μm. However, a reduction of a width Wu at the top of the ridge results in resistance rising, and inherent heat generation degrade the high temperature operation property. In addition to that, high frequency superposition utilized to modulate frequency cannot attain a satisfactory result due to an increased resistance in component devices, and this will be an obstacle of applying this semiconductor laser technology to optical pickup for reading optical disk systems.

As shown in FIG. 12, the film thickness of the p-type cladding layer is 1.0 μm and the width of the bottom of the ridge is 4.0 μm, the operation voltage Vₒₚ of the laser device is 2.61 volts. As the film thickness of the cladding layer is varied to 1.4 μm while the ridge width keeps unchanged, the operating voltage Vₒₚ rises up to 3.17 volts. When the operating voltage of the device is raised especially above 3 volts, an amplitude of the high frequency produced from a high frequency superposing circuit should be extremely high, and this increases a capacity of power supply for the circuit, which virtually makes it impossible to integrate the high frequency superposing circuit into a single chip circuit. Because of this, there have been some difficulties in any application to address downsizing of the optical pickup and reducing inherent heat generation of the electric circuit for plasticizing devices as desired by the market.

As WL is reduced, the width Wu of the top of the ridge is accordingly decreased, because, as detailed below, wet etching is utilized to form the ridges. In order to create the ridges, specified etchant is used to leave mesa etched material having a face at a particular azimuth. An angle cutting sides of the ridges is determined depending upon crystalline orientation. As a result, Wu varies as WL does.

Since a height of the ridges is decreased as the film thicknesses Tp and Tn of the cladding layer are reduced, Wu may take a large value while WL is fixed. However, as will be apparent from the value θ_{⊥} (26°) simulated with the assumption of the cladding layer film thickness of 1.0 μm in Table 1, θ_{⊥} is significantly increased as the film gets thinner. It is desirable that the angle of vertically diverging beam is 25° or less for the semiconductor laser used in optical disk drives dedicated for writing, and above the value, the optical coupling efficiency in relation with the optical disc systems is reduced, leading to an unavoidably serious problem in the application.

When the thickness of the cladding layer is extremely reduced, laser light propagating through waveguide in the active layer leaks both the overlaid and underlaid cladding layer, and when part of the leaky rays trespassing into the n-type GaAs substrate and the p-type GaAs contact layer is absorbed, a waveguide loss α of the active layer is significantly increased (5.6 cm⁻¹). Hence, the real refractive index waveguide laser becomes considerably less advantageous.

To keep stable operation of the optical pickup with high optical throughput, kink should not be observed in the relation between the operating current and the optical output in a predetermined range of the optical output.

FIG. 13 is a graph illustrating kink occurring in the relation between the operating current and the optical output. As shown in the graph, the kink appears as great windings in plotted relation between the operating current Iₒₚ and the optical output Pₒ, and the optical pickup loses stable operation fore and after a kinking location. Allowing for a long term reliability, the optical output at which the kink appears (usually referred to as “kink level”) desirably does not fall in the specified range of the optical throughput, or rather, more desirably it reaches a level as high as possible.

FIGS. 14A and 14B depict a concept of a cause of the kink. As illustrated in FIG. 14A, incoming current is introduced into the active layer 407 to define a light emitting zone. Then, as shown in FIG. 14B, a lateral mode or a distribution of light intensity in parallel with the junction plane of the active layer is changed from a fundamental mode (zero order mode) to a first order mode, and the kink is resulted from this.

In the ridged semiconductor laser having the MQW active layer, a gain factor for the fundamental mode of a single peak distribution of light intensity having its peak at the midpoint is higher than a gain factor for the first or any succeeding order mode under the condition of the low optical output, resulting in a likeliness to stable oscillation. Hence, the semiconductor laser is stable in the fundamental mode till the optical throughput reaches a certain level.

However, in a high throughput condition where the optical throughput is several tens mW or higher or in a high incoming current condition where the current of 100 mA or higher is introduced, a presence of photoelectric field of high intensity somewhat disturbs electron-hole distribution inversion in the center of the ridge where the electron-hole distribution inversion is developed most frequently. This is a phenomenon named “spatial holeburning”. Also, “plasma effect” where an injection of a large number of carriers causes a refractive index to decrease affects a reduction of the refractive index as well, and resultantly, the first or higher order mode produces the maximum gain rather than the fundamental mode, and the mode itself is varied.

In order to reduce an alteration of the lateral mode, it is necessary to retain a fixed differential gain between the fundamental mode and the higher order mode even in the conditions of high optical output and high incoming current. One of solutions to this may be minimizing a differential effective refractive index Δn_{eff}. The smaller differential effective refractive index Δn_{eff}=n_{1eff}−n_{2eff} produces the greater differential gain between the fundamental mode and the higher order mode where Δn_{eff} is a difference between an effective refractive index n_{1eff} for the laser light propagating in the active layer within the ridge and an effective refractive index n_{2eff} for the laser light propagating in the active layer outside the ridge.

Shigihara, in the light of the aforementioned facts, discloses an AlGaAs semiconductor laser in Japanese Patent Laid-Open Publication No. H11-233883, which has a cladding layer structure asymmetrical to an active layer where as a measurement location is farther from the active layer, refractive indices of p-type and n-type cladding layers are accordingly reduced, and the refractive index is higher in the n-type cladding layer than in the p-type cladding layer, or the n-type cladding layer is thicker than the p-type cladding layer. This structure enables Δn_{eff} to decrease by shifting the distribution of light intensity vertical to a junction plane from the active layer to the n-type cladding layer, so that kink occurs with the higher levels of the optical output and the operating current in the laser device. This structure, however, is still seriously defective in practical use.

For instance, the refractive index of InGaAlP cladding layer of a composition represented as In_{0.5} (Ga₁₋ₓ Alₓ)_{0.5}P depends upon an Al ratio in the composition denoted as x. To alter the refractive index, the Al ratio in the composition must be varied during MOCVD (metal-organic chemical vapor deposition) for fabricating laser crystal. The Al ratio for InGaAlP is determined by organic metal gasses used for crystal growth such as TMA (tri-methyl aluminum), TMG (tri-methyl gallium), TMI (tri-methyl indium), and phosphine (PH₃), and flow rates of these process gasses. In order to implement a reproducible crystal growth during a mass-production of the semiconductor laser, it is necessary to calibrate a predetermined value of a massflow controller used to control a flow rate of process gass in a MOCVD apparatus each time the flow rate is changed. Time and cost spent for the structure as disclosed in Japanese Patent Laied-Open Publication No. H11-233883 are too tremendous to realize the mass production of such a laser structure.

Furthermore, the structure disclosed in Japanese Patent Laied-Open Publication H11-233883 is a “pair-ridged” structure where a p-type cladding layer shaped into ridges is covered with insulation film except for an area through which current is injected and a complex refractive index structure where the ridge-shaped p-type cladding layer has its opposite flanks coated with n-type GaAs. The pair-ridged structure has the p-type cladding layer insulated by thin insulation film and is physically fragile, and ineffective leak current is often caused. The complex refractive index structure is not appropriate to use for laser to attain higher optical throughput.

Another solution of reducing a change in the lateral mode is narrowing the width WL of the bottom of the ridge. When the ridge is narrowed, Δn_{eff} does not change, but instead, laser light, which propagates in the active layer around the ridge where the distribution of light intensity has a peak in the higher order mode, behaves as if it is in the so-called “leaky mode” where light leaks off the cladding layer and dissipates. This results in a loss coefficient in the higher order mode considerably increasing, compared with that in the fundamental mode. Since a current pinching width is reduced, the gain around the ridge, which is required for the high order mode oscillation, is hard to attain. All these factors restrain the high order mode. In the comparative structure, however, pinching the ridge width is not so simple to perform.

In the ridged semiconductor laser used for the optical pickup dedicated to optical discs, a GaAs substrate is used which has a major surface (100) or a major surface tilted by several degrees to 15 degrees from (100) toward a crystal axis of [110], for example. Although the current blocking layer is formed by means of crystal growth after the ridge is shaped, the coating on the opposite flanks of the ridge must also have good crystallinity to grow the current blocking layer of good crystallinity. For that purpose, the opposite flanks of the ridges are etched away by means of reaction rate-determining wet etching till (111)A surface is exposed. By virtue of this fashion of etching, the resultant ridge is shaped to have a trapezoidal cross-section as shown in FIG. 11 or FIG. 14A, and as the width WL at the bottom of the ridge is reduced, the width Wu at it top is accordingly decreased. For example, when WL is 4 μm, Wu may be approximately 2 μm. As previously mentioned, a reduction of Wu causes a device resistance to significantly rise, and this brings about an increase of applied voltage essential for operation, which, in turn, causes some trouble in applications to the optical disc systems.

Allowing for these respects, Nomura et al. and Miyashita et al. reported that they had improved high power laser by using dry etching to shape ridges having almost rectangular cross-sections (see Preliminary Articles for Lectures at the 47th Confederation Meeting of the Societies of Applied Physics, 29a-N-8 and 29a-N-7, March, 2000). However, upon dry etching compound semiconductor material, uniform etching is not easy in an in-plane direction.

When wet etching is used, there is provided an etching stop layer of semiconductor crystal which is etched at a significantly lower rate than the ridge, so as to have even etching depth. The etching stop layer may be made of compound semiconductor crystal having a different composition from the compound semiconductor crystal right below the ridge. The dry etching, in contrast, is inappropriate to reaction rate-determining process, and it is hard to provide the etching stop layer by dry etching. Thus, it is hard to precisely control ridge dimensions which affect a regulation of the angle of diverging beam and the kink occurrence level, and the dry etching proves to lead poor productivity.

### SUMMARY OF THE INVENTION

According to one embodiment of the present invention, there is provided a semiconductor laser which comprises: a cladding layer of a fist conductivity type; an active layer provided over the cladding layer of the first conductivity type; a cladding layer of a second conductivity type provided over the active layer, the cladding layer of a second conductivity type having a ridge shaped at its top, the ridge extending in parallel with a direction of laser resonance; and a current blocking layer provided on opposite flanks of the ridge,

the cladding layers of the first and second conductivity types being made of semiconductor material having substantially the same composition, and

a thickness of the cladding layer of the first conductivity type is larger than a thickness of the cladding layer of the second conductivity type including the ridge.

According to another embodiment of the present invention, there is provided a semiconductor laser which comprises: a first cladding layer having a vertically uniform distribution of refractive index throughout its thickness; an active layer provided over the first cladding layer; and a second cladding layer provided over the active layer, the second cladding layer having a vertically uniform distribution of refractive index throughout its thickness, and having a ridge extending in parallel with a direction of laser resonance,

the first and second cladding layers being made of semiconductor material having substantially the same composition,

a thickness of the first cladding layer is larger than a thickness of the second cladding layer including the ridge, and

an asymmetrical distribution of light intensity being formed, the distribution showing its peak in a vicinity of the active layer and relatively rapidly dissipating in the second cladding layer while relatively gradually degrading in the first cladding layer.

According another embodiment of the present invention, there is provided a method of manufacturing a semiconductor laser which comprises: forming a first cladding layer of a fist conductivity type, the first cladding layer having a vertically uniform distribution of refractive index throughout its thickness; forming an active layer over the first cladding layer; forming a second cladding layer of a second conductivity type over the active layer, the second cladding layer having a vertically uniform distribution of refractive index throughout its thickness, and the second cladding layer being made of semiconductor material having substantially the same composition as that of the first cladding layer; forming an etching stop layer over the second cladding layer, the etching stop layer being made of semiconductor material of a different composition from that of the second cladding layer; forming a third cladding layer over the etching stop layer, the third cladding layer having a vertically uniform distribution of refractive index throughout its thickness, the third cladding layer being made of semiconductor material of the second conductivity type and having substantially the same composition as that of the second cladding layer, and a sum of a thickness of the third cladding layer and a thickness of the second cladding layer is smaller than a thickness of the first cladding layer; providing a mask in a striped pattern over the third cladding layer; selectively etching the third cladding layer with a reaction rate-determining wet etchant to remove the third cladding layer without the mask thereon and shape ridge; and providing a current blocking layer on the opposite flanks of the ridge.

### BRIEF DESCRIPTION OF THE DRAWINGS

The present invention will be understood more fully from the detailed description given herebelow and from the accompanying drawings of the embodiments of the invention. However, the drawings are not intended to imply limitation of the invention to a specific embodiment, but are for explanation and understanding only.

In the drawings:

FIG. 1 is a partial sectional perspective view showing a major portion of an exemplary semiconductor laser according to the present invention;

FIG. 2 is a sectional view showing an area around a light emitting end surface of the semiconductor laser in FIG. 1;

FIG. 3 is a sectional view showing an area around the center of an oscillator of the semiconductor laser in FIG. 1;

FIGS. 4A and 4B are schematic diagrams showing distributions of a refractive index and light intensity in the semiconductor laser; FIG. 4A shows a sample simulated in the semiconductor laser according to the present invention while FIG. 4B shows a sample simulated in a comparison semiconductor laser where upper and lower cladding layers have the same film thickness;

FIGS. 5A and 5B are schematic diagrams showing a shape of a cross section of a ridge; FIG. 5A is a sample simulated in the semiconductor laser while FIG. 5B is a sample simulated in the comparison semiconductor laser where upper and lower cladding layers have the same film thickness;

FIG. 6 is a list containing data on an angle of diverging light produced by a real refractive index waveguide semiconductor layer according to the present invention;

FIG. 7 is a partial cross-sectional perspective view showing an InGaAlP semiconductor laser fabricated without using facet window;

FIG. 8 is a partial cross-sectional perspective view showing another exemplary semiconductor laser according to the present invention;

FIG. 9 is a sectional view showing a high power semiconductor laser according to the present invention;

FIG. 10 is a schematic diagram showing still another exemplary semiconductor laser according to the present invention;

FIG. 11 is a schematic diagram showing a comparative InGaAlP ridged real refractive index semiconductor laser;

FIG. 12 is a list containing data of an angle of diverging light produced in both the real refractive index waveguide laser and a complex refractive index waveguide laser;

FIG. 13 is a graph illustrating a kink occurring in the relation between the operating current and the optical output; and

FIGS. 14A and 14B are a diagrams showing a concept of a cause of the kink.

### DETAILED DESCRIPTION

Some embodiments of the present invention will now be described in detail with reference to the accompanying drawings.

### First Embodiment

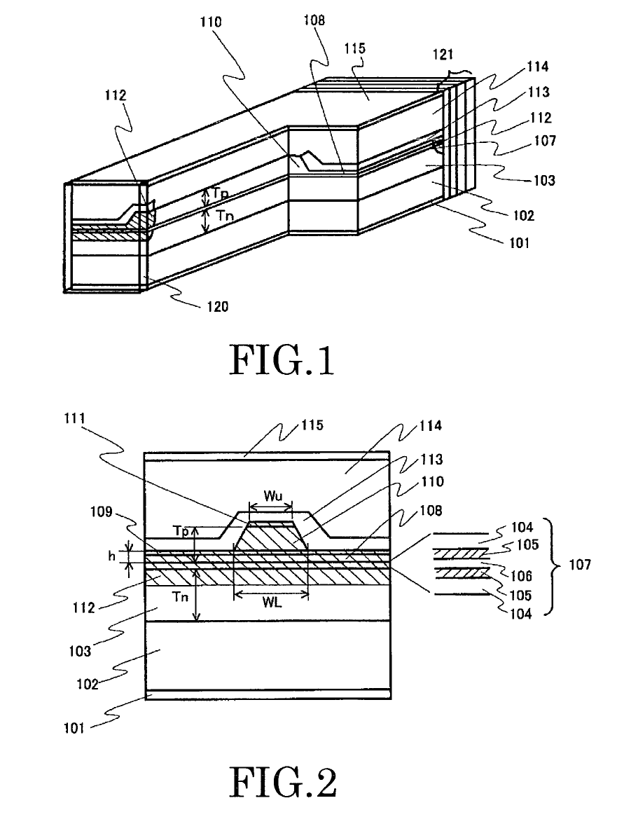

FIG. 1 is a partial cross-sectional perspective view showing a major portion of a semiconductor laser according to the embodiment of the present invention.

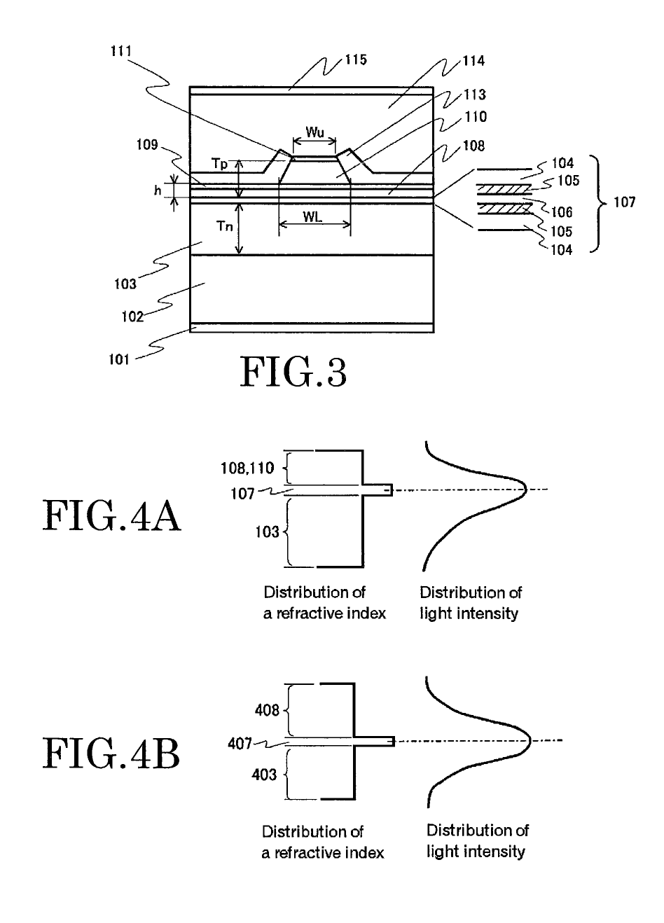

FIG. 2 is a cross-sectional view near the light emitting facet of the semiconductor laser in FIG. 1, while FIG. 3 is a cross-sectional view of an area around the center of an oscillator of the same. FIGS. 2 and 3 illustrate sectional structures taken along a plane in parallel with the light emitting facet of the laser.

First described are major components of this embodiment of the semiconductor laser, including a crystal substrate 102 of a first conductivity type which is superposed with an first cladding layer 103 of the first conductivity type, an MQW active layer 107, a second cladding layer 108 of a second conductivity type, and a etching stop layer 109 of the second conductivity type. These are all laid one over another in order as listed above into a multi-layered structure, and this is further superposed with a third cladding layer 110 of the second conductivity type and a conduction promoting layer 111 of the second conductivity type which are shaped in ridge. The ridge has its opposite flanks coated with a current blocking layer 113 of the first conductivity type, and a contact layer 114 of the second conductivity type is overlaid to cover the top. In an underside of the substrate 102, an electrode 101 is provided for the first conductivity type, and on the contact layer 114, an electrode 115 is provided for the second conductivity type.

In accordance with the embodiment of the present invention, the first, second and third cladding layers 103, 108 and 110 are identical in Al ratio of the composition, and the ratio is uniform throughout three of the layers. A film thickness Tn of the first cladding layer 103 is larger than a sum of film thicknesses of the second and third cladding layers 108 and 110.

In this manner, angles of vertically and horizontally diverging beams can be adjusted suitably, kink is prevented, and a resistance of a device can be reduced. These effects will be described later.

At the same time, concordance of the Al ratio of the composition among the cladding layers and uniformity of the Al ratio throughout the cladding layers would promote improving productivity because omission of an annoying task of calibrating a massflow controller required in the prior art.

Now, further details will be given regarding a structure of each component of the semiconductor laser according to the embodiment of the present invention.

An n-type GaAs substrate can be used for the crystal substrate 102 of the first conductivity type, and the overlying first cladding layer 103 may be of an n-type In_{0.5} (Ga₁₋ₓ Alₓ)_{0.5}P layer where the Al ratio x of the composition is equal to 0.7.

The active layer 107 may be of an MQW (multiple quantum well) configuration where an undoped InGa p-type well layer 105 and an undoped In_{0.5} (Ga_{1-y} Al_{y})_{0.5}P p-type barrier layer 106 are alternately stacked one over another and interposed between a pair of undoped In_{0.5} (Ga_{1-y} Al_{y})_{0.5}P optical guide layers 104. Zero % to 2% of compressive distortion is applied to the MQW configuration. Application of the compressive distortion is effective to increase a differential gain in the active layer and to decrease an oscillation threshold Iₜₕ. This also intends to increase a slope efficiency SE to attain enhanced optical throughput, and a gain of the targeted oscillation mode or the transverse electric (TE) mode becomes higher than that of the transverse magnetic (TM) mode, which is advantageous to stabilize the oscillation mode. In FIGS. 2 and 3, a DQW (double quantum well) configuration is depicted where the well layer consists of two-layer stratum. In order to fabricate the InGaAlP laser by which a high output more than several tens mW can be efficiently obtained, it is desirable to provide 2 to 5 of wells each of which has a thickness of a well layer ranging from 4 nm to 7 nm so that the total film thickness obtained through a multiplication of the number of wells by the well layer thickness ranges from 100 nm to 300 nm.

The Al ratio y may be varied in a range from 0.4 to 0.6 for the barrier layer 106 and the optical guide layer 104 so as to retain a differential band gap from those of the cladding layers 103 and 108, and thereby reducing current leak caused by carrier overflow during high temperature operation with high output to attain the desired improved operation. This prevents unsatisfactory carrier injection due to a discrete band gap that is resulted from an excessive differential band gap from that of the cladding layer.

The second cladding layer 108 over the MQW active layer 107 may be made of a material of a composition represented as In_{0.5} (Ga₁₋ₓ Alₓ)_{0.5}P. The second cladding layer along with the overlaid etching stop layer provide a flattened surface of the cladding layer aside the ridge, and this helps to precisely adjust a height of the ridge which greatly affects the angle of diverging beam and the effective refractive index Δn_{eff}, which enables a fabrication of the laser device that offers excellent reproducibility of properties. The Al ratio x of the composition of the second cladding layer 108 also equals 0.7.

The etching stop layer 109 provided over the second cladding layer 108 may be a semiconductor material of a composition represented as In_{q} (Ga_{1-z} Al_{z})₁₋_{_{q}}P while the overlaid third cladding layer 110 may be made of a material of a composition of p-type In_{0.5} (Ga₁₋ₓ Alₓ)_{0.5}P. The Al ratio in the composition of the third cladding layer 110 may be identical with that used for the first and second cladding layers, 0.7.

The conduction promotion layer 111 provided over the ridge may be of InGaP having an intermediate band gap relative to the band gaps of the third cladding layer 110 and the contact layer 114. On the other hand, the current blocking layer 113 provided on the opposite flanks of the ridge may be of n-type InAlP transparent to any light emitting wavelength, and the contact layer 114 may be of narrowed band gap p-type GaAs.

The facet emitting laser beam is covered with a low reflection film 120 having a laser light reflectivity of 15% or below while the opposite facet is covered with a high reflection film 121 having a laser light reflectivity of 90% or over. In this way, the facet can efficiently emit laser light.

In the aforementioned structure, it is preferable that the film thickness Tn of the first cladding layer is greater than the sum of the film thicknesses of the second and third cladding layers 108 and 110. Effects of this asymmetrical structure embodied as Tn>Tp will be described below.

FIGS. 4A and 4B are schematic diagrams showing distributions of the refractive index and light intensity of the semiconductor laser; FIG. 4A is a sample simulated in the semiconductor laser according to the embodiment of the present invention while FIG. 4B is a sample simulated in a comparison semiconductor laser where upper and lower cladding layers have the same film thickness.

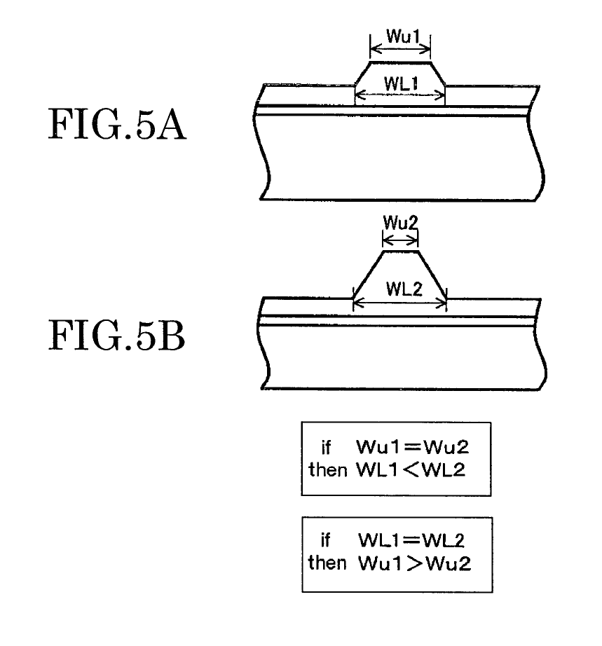

FIGS. 5A and 5B are schematic diagrams showing a shape of a cross section of a ridge; FIG. 5A is a sample simulated in the semiconductor laser while FIG. 5B is a sample simulated in the comparison semiconductor laser where upper and lower cladding layers have the same film thickness.

First, as shown in FIG. 4B, when the upper and lower cladding layers 103 and 108 are identical in film thickness, a distribution of light intensity vertical to a junction plane is equivalent to a vertically symmetrical distribution about the center axis of the active layer 107.

In the embodiment of the present invention as shown in FIG. 4A, however, the upper and lower cladding layers are vertically asymmetrical in the term of the film thickness. The asymmetrical distribution of light intensity shows its peak in the vicinity of the active layer 107, and after being maximized, it rapidly dissipates in the p-type cladding layers 108 and 110 while gradually degrades in the n-type cladding layer 103. Thus, a ratio of the distribution of light in the upper cladding layers 108 and 110 can be reduced. In this way, a reduction of the film thickness of the p-type cladding layers 108 and 110 does not cause any change in property, e.g., no change in application factors nor in the angle θ_{⊥} of diverging beam, and no increase in waveguide loss α, neither. Thus, in accordance with the embodiment of the present invention, the vertically asymmetrical distribution as shown in FIG. 4A permits a reduction of the film thickness in the upper cladding layers 108 and 110 without any loss or change of advantageous features of the real refractive index waveguide laser.

When the upper cladding layers 108 and 110 get thinner as mentioned above, the width WL of the ridge can be reduced without rise of the resistance of the device.

When vertically asymmetrical cladding layers are provided as illustrated in FIG. 5B, properties, such as an angle of diverging light, derived from the laser having the cladding layers of 1.1 μm film thickness do not satisfy the requirements. Furthermore, when a ridge is shaped in a suitable manner by means of wet etching, an inclination angle of the opposite sides of the ridge is determined and fixed depending upon crystalline azimuth, and therefore, a width Wu2 of the top of the ridge relative to the width WL2 of the ridge at its bottom is also fixed. Consequently, although the ridge width WL2 can be reduced to its lower limit ranging 4.0 μm to 4.5 μm to keep the device resistance in an appropriate range of the device resistance, it is not acceptable to further reduce the limit.

The embodiment of the present invention, however, permits a reduction of the film thickness of the cladding layers 108 and 110 without any loss or change in the properties of the real refractive index waveguide laser as shown in FIG. 4A. Resultantly this permits a reduction of the width WL1 of the bottom of the ridge without decreasing the width Wu1 of the top of the ridge. In other words, without a rise of the device resistance which may cause a trouble in a practical use, the ridge can be shaped with the desired width WL 1. Thus, the high power semiconductor laser of efficient high temperature operation can be implemented without any loss or change in the advantageous properties of the real refractive index waveguide laser.

The ridge can be shaped with the considerably increased width Wu1 at its top while the width WL1 leaves unchanged. As a result, the device resistance can be reduced, and the features of the high temperature operation and the high throughput can be further improved.

Although it is not disclosed in Japanese Patent Laid-Open Publication No. H11-233883, the asymmetrical cladding layer structure exhibits an asymmetrical distribution of light intensity, and a peak of FFP (far field pattern) tends to slightly shift to the n-type material. The inventors, in their attempt and review, have found that an inclination angle Δθ_{⊥} is within 0.5° when practical device parameters are applied, and this is an acceptable value if a measurement error and an assembly error are taken into consideration.

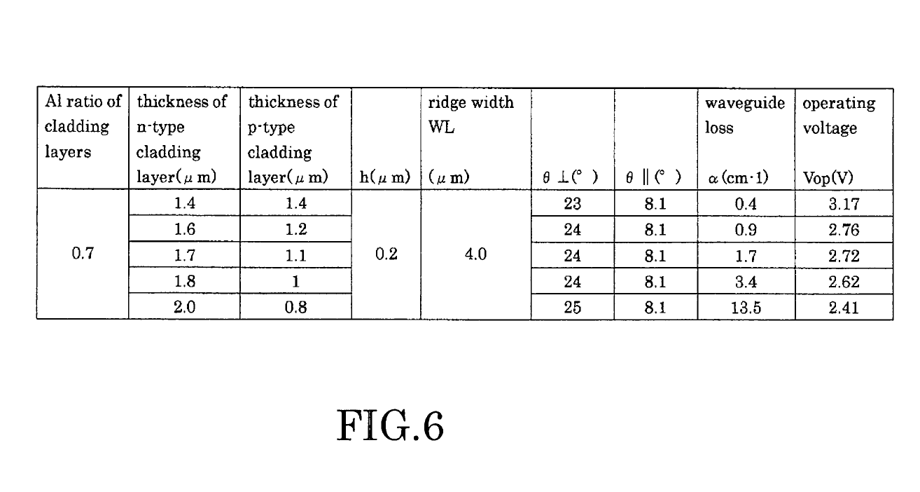

FIG. 6 is a list containing data of the angles of diverging beam in the real refractive index waveguide laser. The data contains the angles θ_{⊥} and θ_{∥} of diverging beam and a waveguide loss α which are obtained by changing the total film thicknesses of the p-type cladding layers and the n-type cladding layers, respectively, under the conditions that a width WL of the bottom of the ridge is equal to 4.0 μm and the sum of the film thicknesses of all the cladding layers (Tp+Tn) is constant (2.8 μm).

As shown in FIG. 6, the operating voltage Vop is 2.62 volts in the asymmetrical cladding layer structure according to the embodiment of the present invention under the conditions that the film thickness of the n-type cladding layers is 1.8 μm, the film thickness of the p-type cladding layer is 1.0 μm, and the width of the bottom of the ridge is 4.0 μm. In contrast, the operating voltage is 3.17 volts in the comparative asymmetrical cladding layer structure with film thickness 1.4 μm of the cladding layers. The asymmetrical cladding structure according to the embodiment of the present invention proves a capability of decreasing operating voltage as much as 0.55. This enables a high frequency superposition IC design with a full design margin, which brings about an improved high power semiconductor laser suitable to applications of the optical pickup dedicated to optical disc systems.

If the ridge width WL is further reduced, the embodiment of the present invention will be more useful. In a given range where WL=2.5 to 3.5 μm, when the ridge is shaped with the width WL of 3.0 μm, the resultant Vop would not exceed 3 volts, or stay as low as 2.8 volts. As is apparent from the above discussion, if the ridge is shaped with the reduced width WL, the kink occurs at the higher levels of factors, and an increase in the angle θ_{∥} is permissible, in this case, up to 9 degrees. This enables the higher optical throughput, and a high power semiconductor laser dedicated to optical disc systems can be implemented with an improved optical coupling efficiency attained.

When WL is less than 2.5 μm, the kink level shifts higher at the room temperature, but under the condition of a higher temperature of 70° C. or above, inherent heat generation observed at the ridge degrades the temperature property. A processing procedure using reaction rate-determining etchant can no longer be applied. Thus, it is desirable that the ridge width WL falls in a range from 2.5 μm to 3.5 μm.

Turning to FIG. 6 again, with a given range of Tp=1.0˜1.4 μm, the angle θ_{⊥}=23˜24 degrees and θ_{∥}=8.1°, and these angles prove to satisfy with the requirements for light source used to write in optical disks. If Tp is limited to 1.0, the waveguide loss α is 3.4 cm⁻¹. This is lower than a half of the waveguide loss of the complex refractive index waveguide laser, or a half of 7 cm⁻¹, and is satisfactory to obtain the advantageous features of the complex refractive index waveguide laser, namely, features of low threshold value and high efficiency. The inventors also evaluated that with a given range of Tp+Tn from 2.5 μm to 3.5 μm, certainly the angle of divergent light θ_{⊥} ranges from 21 to 24 degrees, and for any value in the range, the embodiment of the present invention gives satisfactory results.

In the semiconductor laser according to the embodiment of the present invention, although shaped in raised stripes as shown in FIGS. 2 and 3, the ridges in third cladding layer 110 has their respective opposite flanks covered with the InAlP current blocking layer 113 which is of compound semiconductor material having a larger band gap and a lower refractive index than InGaAlP of the cladding layer 110. Thus, this acts to pinch a flow of incoming current in the ridges, and the laser light propagating in the active layer 107 is confined in a waveguide in parallel with the junction plane due to the differential refractive index in the ridges, which prevents the laser light propagating the active layer 107 from being absorbed by the current blocking layer 113. The real refractive index waveguide structure enables an implement of the high efficiency and high power semiconductor laser dedicated to optical disk systems.

Also, in the semiconductor laser according to the embodiment of the present invention, as illustrated in FIG. 2, zinc (Zn) is diffused, and a Zn diffused region 112 is defined to serve as a window area in the vicinity of the facets of the laser chip. Due to the diffused Zn, the well layer 105 and the barrier layer 106 in the MQW active layer 107 loses order in the vicinity of the facets, and the band gap therearound can be increased compared to the inner portion of the active layer 107. Thus, even when the laser is operating in a high output condition, the band gap of the active layer 107 is prevented from decreasing in the vicinity of the facet in the chip, namely, “compression of the band gap” is avoided, and thus, light absorption in the active layer is reduced in the vicinity of the facet. The light absorption in the vicinity of the facet, and the heat generation resulted from the non-emitting recombination of electrons with holes as a result of the light absorption no longer cause irreversible catastrophic optical damage (COD), and thus a reliable high power laser is attained.

In the above-mentioned embodiment, a case where the thickness h of the p-type cladding layers 108 and 110 other than the ridge is 0.2 μm has been explained. The thickness h may have upper and lower limits that guarantee an allowable range of the device properties. An increase in the thickness h leads to a reduction of the ridge height (=Tp−h) and a decrease of Δn_{eff}, which resultantly attains a raised level of the factors in kink, while an insufficiently large value of h may get the θ_{∥} of 7 degrees or less that does not meet the requirement. For the purpose of gaining the satisfied properties of high throughput and reasonable angle θ_{∥}, the thickness h must be in a range from 0.2 μm to 0.3 μm.

With these settings, an improved InGaAlP semiconductor laser suitable for use with DVD-R/RW/RAM can be implemented, which is operable with a short band width of 650 nm to 660 nm, continuous wave (CW) output of 50 mW, pulse output 70 mW at the maximum operating temperature of 70° C.

The semiconductor laser configured in a fashion as mentioned above is manufactured in the following procedure.

First, the n-type GaAs substrate 102 is used for the substrate having a major surface (100) which has a mirror polished surface having an off-angle from 5 degrees to 15 degrees in a direction of [011], thereby preventing natural superlattice during the crystal growth to obtain the optimum crystalline structure to oscillate laser for short wave radiation of 670 nm or below. Crystal growth by reduced pressure MO-CVD results in the n-cladding layer 103 being deposited over the substrate 102. In the subsequent process steps, the similar MO-CVD crystal growth apparatus is used for a deposition of all the compound semiconductor layers. The reduced pressure MO-CVD enables growth of crystals of appropriate reproducibility and desired quality. An n-type GaAs buffer layer or an n-type InGaP buffer layer is interposed between the substrate 102 and the cladding layer 103 so as to improve crystallinity of the cladding layer and an overlaid crystal layer.

After the optical guide layer 104, the well layer 105, and, the barrier layer 106 are deposited over the cladding layer 103, further the well layer 105 and the barrier layer 106 are alternately formed succeedingly several times, and a subsequence deposition of the optical guide layer makes the MQW active layer complete. The InGaP active layer has an In ratio in a composition slightly lower than a valanced matching to a composition of GaAs, and lattice intervals in the InGaP crystals are adjusted to be 0 to 2% greater than those of the substrate 102. This enables zero to 2% compressive distortion in the MQW active layer.

The compound semiconductor of the second conductivity type, or p-type In_{0.5} (Ga₁₋ₓ Alₓ)_{0.5}P second cladding layer 108 is formed over the MQW active layer 107.

The compound semiconductor of the second conductivity type, or p-type In_{q} (Ga_{1-z} Al_{z})_{1-q} P etching stop layer 109 is formed over the second cladding layer 108. The etching stop layer 109 has a composition in which the Al ratio is lower than that of the cladding layer under the assumption as q=0<q<1, and, 0≦z<y, while having a band gap larger than that of the MQW active layer 107. Having a lower Al ratio than the cladding layer 108, the etching stop layer 109 delays a reaction with the reaction rate-determining wet etchant used to shape the ridges, and it automatically interrupts the etching so as to accurately shape the ridges.

Having a band gap wider than that of the active layer 107, the etching stop layer 109 avoids absorbing the trespassing laser light or leaky rays when a distribution of light intensity of the laser light propagating in the active layer 107 expands in the etching stop layer 109, and in this way, good laser properties are maintained.

A p-type In_{0.5} (Ga₁₋ₓ Alₓ)_{0.5}P third cladding layer 110 of the second conductivity type is formed over the etching stop layer 109. The cladding layer is selectively etched away to leave raised stripes in the surface as more detailed below, and the ridged cladding layer is configured. The third cladding layer is identical with the second cladding layer in Al ratio x in a composition, which is approximately 0.7.

The InGaP conduction promoting layer 111 is provided over the third cladding layer and causes fading of a clear discreteness of the band gap between the third cladding layer 110 and the p-type GaAs contact layer 114. This enables laser to oscillate with low voltage and attains an improved high temperature operation.

After a GaAs gap layer is formed over the multi-layered structure configured so far, the crystallized substrate is taken away from an MOCVD apparatus, and Zn is selectively diffused only in an area in the vicinity of the facets in the device. One of the ways of selective diffusion of Zn is carried out in the following steps: After a dielectric film of SiO₂ is formed over the entire surface crystallized by crystal growth, only part of the surface is removed by photolithography method, and a GaAs layer containing Zn is deposited in the residual region by crystal growth. The substrate undergoes annealing for solid-phase diffusion.

Alternatively, a dielectric film such as ZnO₂ containing Zn at a high concentration level is formed, and thereafter, the dielectric film is selectively removed by the photolithography method, then a solid-phase diffusion is performed at the remaining portion by an annealing. A length of such Zn diffused region along an extension of a resonator (referred to as “window length”) is appropriately 10 μm to 40 μm for each facet. With the window length less than 10 μm, cutting the wafer by cleavage to expose the facets cannot ensure a positional precision, and sufficient effects of the window are not exerted. With the window longer than 40 μm, however, light absorption in the window region becomes as high as 60 cm⁻¹ which proves to be a significant loss. The resultant reduction of emission efficiency and the increase of oscillation threshold produce properties that make the device inappropriate for the use to the optical disc systems.

After the Zn diffused region 112 is formed, the dielectric insulating film of SiO₂ is formed and then patterned into stripes by photolithography method. The remaining third cladding layer 110 other than the strips is removed with reaction rate-determining etchant to shape the raised stripes or ridges. The etching stop layer 109 defines a terminating point of the etching, and thus, the ridges can be created in such a highly reproducible manner. Although the etching stop layer 109 may be left on the wafer, it may be eliminated with diffusion rate-determining etchant after the shaping of the ridges in case it may be a potential risk for leak current flowing via the flanks of the ridges.

After shaping the ridges in the third cladding layer 110, once again, only the part of the dielectric insulating film right above the Zn diffused region is removed from the surface of each ridge by photolithography method, and then, the wafer is crystallized in the MOCVD apparatus to have InAlP deposited on the etched region aside the ridge and the top of the ridge without the dielectric insulating film by means of selective crystal growth. In this way, the current blocking layer 113 is formed. The InAlP current blocking layer is hard to selectively grow to the desired thickness if the thickness is above a certain level, while the thinly deposited film provides unsatisfied effects of current blocking. Desirably, the thickness ranges from 0.2 to 0.8 μmₒ

After the current blocking layer 113 has grown, the crystallized substrate is taken out of the MOCVD apparatus to etch the dielectric insulating film away. In the MOCVD, again, the compound semiconductor of the second conductivity type or the p-type GaAs contact layer 114 is deposited, which provides an Ohmic contact with the p-side electrode 115.

After the procedure of the crystal growth as mentioned above, the p-type electrode 115 of AnZn/Au is formed by vapor deposition, and on the opposite side of the wafer, the n-type GaAs substrate is polished and finished in a thickness ranging from 60 μm to 150 μm to create the n-side electrode 101. With the wafer finished in this way, the wafer is cleaved to create facets, and one of the facet from which laser is to be emitted is coated with a low reflective film having a reflectivity of 20% or less by means of ECR sputtering while the other facet is covered with a multi-stratum film to have a high reflective film having a reflectivity of 90% or above. The resultant wafer is diced in chips, and finally finished in semiconductor laser chips. Through this procedure, the high power semiconductor laser of improved efficiency and excellent operability at high temperature can be implemented.

### Second Embodiment

Another semiconductor laser according to the second embodiment of the present invention will now be described. In this embodiment, the window is not defined in the facet, unlike the aforementioned embodiment.

In a laser device of optical throughput ranging from 7 mW to 20 mW dedicated to optical disk systems such as DVD-ROM, the window at the facet is not essential. Thus, since the step of Zn diffusion as described in the previous embodiment is omitted, the number of process steps is reduced, and the manufacturing cost is reduced.

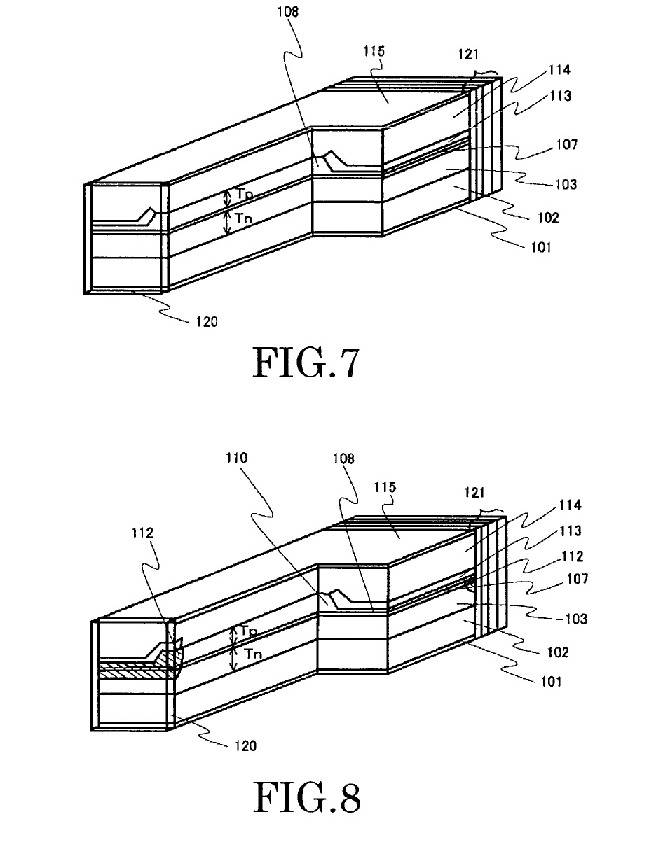

FIG. 7 is a partial sectional perspective view showing an InGaAlP semiconductor laser fabricated without using the window at the facet of the wafer. Like reference numerals denote similar components as described in conjunction with FIGS. 1 to 6, and any particular explanation on those components is omitted.

In this embodiment, also, both the real refractive index waveguide structure and the asymmetrical cladding layer structure are used to raise a level of factors in kink or a level of optical output so as to obtain improved performance of high efficiency and low threshold. Thus, the semiconductor laser, which can restrain heat generation of a drive circuit and have improved features of high yield and excellent productivity, can be implemented.

When used for light source of DVD-ROM, the semiconductor laser desirably has the cladding layers 103 and 108 of InGaAlP of which Al ratio is approximately 0.7. The requirement for the angle θ_{⊥} of diverging light is 25 to 32 degrees, and accordingly, it is desirable that the total thickness (Tp+Tn) of the cladding layers ranges from 1.0 μm to 2.5 μm, preferably from 1.5 to 2.5 μm.

It is preferable that the total thickness of the MQW structure of the active layer 107 ranges 100 nm to 300 nm, and that three to five of the well layers are provided in a thickness from 4 to 7 nm. Also, preferably, the thickness of the p-type cladding layer other than the height of the ridge ranges from 0.08 μm to 0.2 μm.

### Third Embodiment

A third embodiment of the semiconductor laser will be described. This is an application of the embodiment of the present invention to an AlGaAs high power semiconductor laser operable with 780 nm bandwidth and used for rewritable optical disc drives such as CD-R/RW.

FIG. 8 is a partial sectional perspective view showing the embodiment of the semiconductor laser. Like reference numerals denote the corresponding components throughout FIGS. 1 to 7, and any detailed description on the similar components is omitted.

In this embodiment, the cladding layers 103, 108, 110 are made of material having a composition of AlₓGa₁₋ₓAs where an Al ratio x ranges from 0.4 to 0.5. The current blocking layer 113 is also made of material having a composition of Al_{y}Ga_{1-y}As where the Al ratio y ranges from 0.51 to 0.6. The MQW active layer 107 is comprised of an AlᵤGa₁₋ᵤAs well layer and an AlᵥGa₁₋ᵥAs barrier layer where the Al ranges u and v are expressed as u=0.1˜0.2 and v=0.2˜0.35. With these parameter settings, a satisfactory light confinement is carried out to implement the real refractive index waveguide semiconductor laser of low threshold and high efficiency and operable with a 780 nm bandwidth.

In an application for CD-R/RW, the requirements for the angles of diverging light are as θ_{⊥}=13 degrees˜19 degrees, and θ_{∥}=7 degrees to 9 degrees. In order to attain the suitable angles for rewritable optical disks, the total thickness Tp+Tn of the cladding layers ranges from 4 μm to 6 μm. As a result of a simulation, in order to have the required angle θ_{⊥} in the asymmetrical cladding layer structure and simultaneously to attain the satisfactory effects, the optimum range is expressed as Tp=2 to 3 μmₒ

### Forth Embodiment

A fourth embodiment of the high power semiconductor laser according to the embodiment of the present invention will be described.

The optical throughput of light source required for 16 speed CD-R/RW is 160 mW on the pulse drive basis, and the level of factor in kink must be above that. In order to meet the requirements for the angle θ_{∥} and the kink level, the width WL of the ridge at its bottom ranges from 1 to 3 μm, preferably 2 μm, and more preferably less than 2 μm.

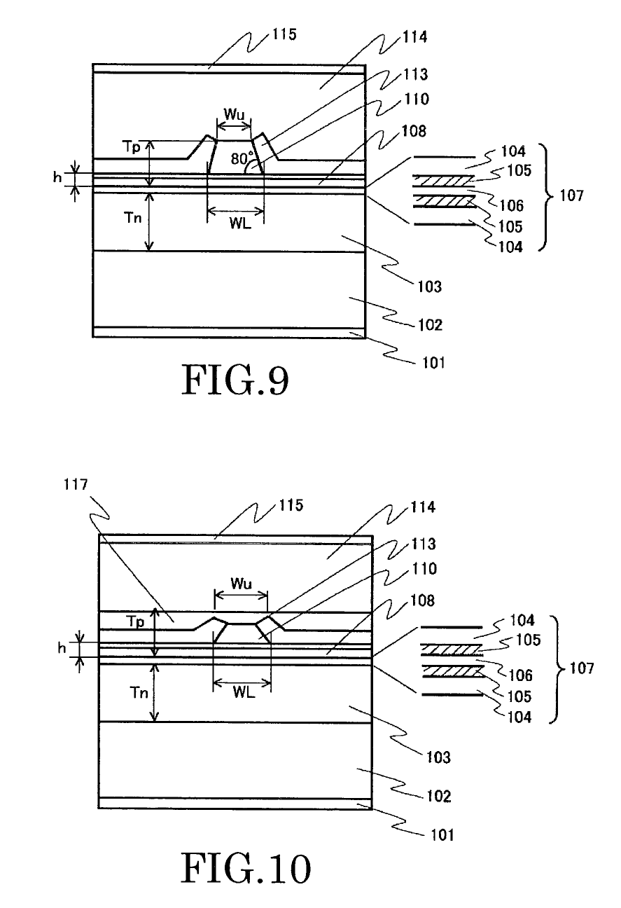

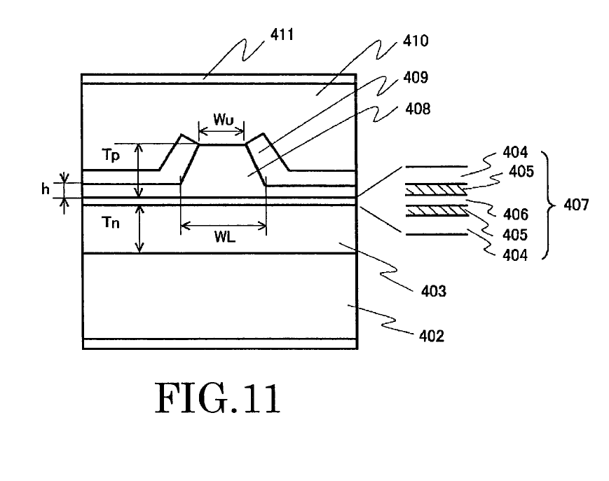

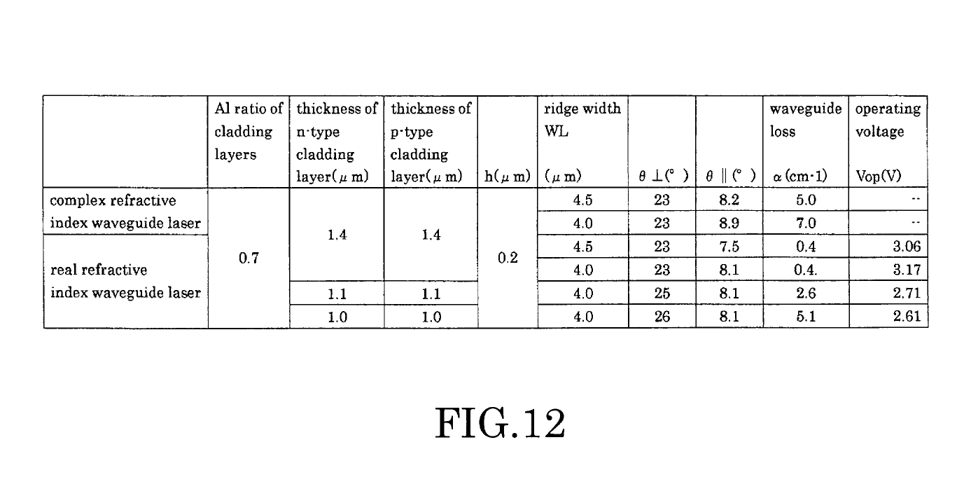

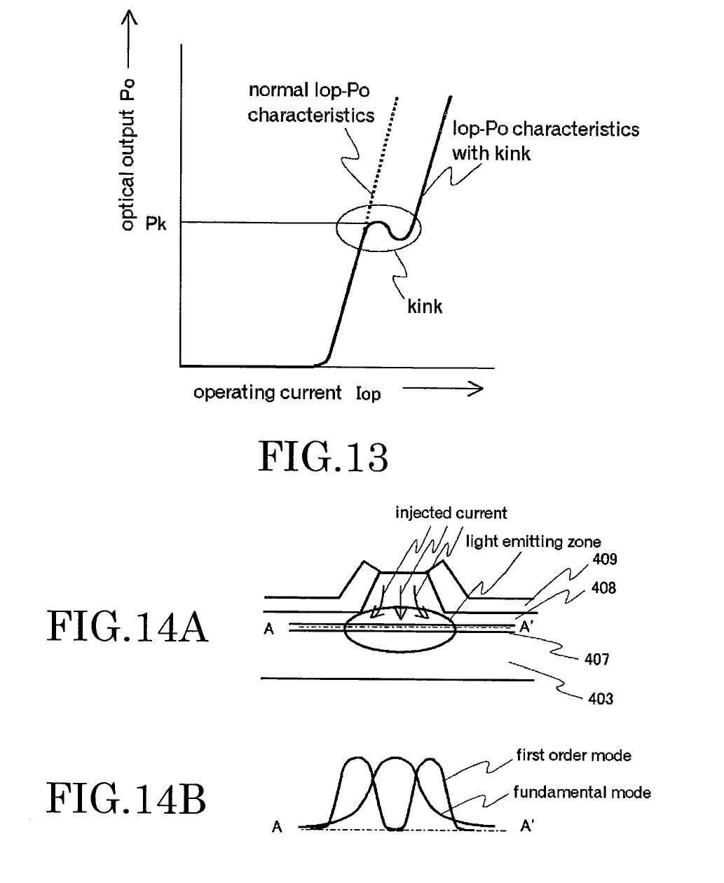

FIG. 9 is a sectional view showing the semiconductor laser meeting the requirements as mentioned above. In this figure, a sectional structure taken along the plane of the laser emitting facet is seen. Like reference numerals denote the similar components as described in conjunction with FIGS. 1 to 8, and any detailed description on the components is omitted.

In this embodiment, the ridge width WL ranges 1 to 3 μm, and the ridges are shaped with such an extremely tight width. For the narrow and tall ridges, the opposite flanks of the ridges must incline at an angle of 80° or steeper. However, it is very difficult to shape such steep ridges through reaction rate-determining etching. Thus, a wet etching with diffusion rate-determining etchant or RIE (reactive ion etching) may be substituted. These substitutional methods cause an uneven inplane etching rate in an ordinary cladding layer structure, or in other words, it cannot attain good balance among properties, which leads to a defect of a reduced yield of devices. In combination with the asymmetrical cladding layer structure, such imbalance is recovered, and a good productivity of the high power semiconductor laser can be attained.

FIG. 9 depicts simply an inner structure of the chip, but similar to the Embodiment 1, COD can be inhibited by providing the window region that reasonably loses order due to Zn diffused in the vicinity of the facets.

This embodiment can similarly be applied to the InGaAlP high power laser.

### Fifth Embodiment

A fifth embodiment of the semiconductor laser according to the present invention will be described, which is an application having a burying cladding layer structure.

FIG. 10 is a schematic diagram showing the exemplary semiconductor laser. FIG. 10 depicts a sectional structure of the laser taken along the plane of the light emitting facet. Like reference numerals denote the similar components as described in conjunction with FIGS. 1 to 9, and any detailed description on the components is omitted.

The burying cladding layer structure is fabricated in the following steps: The third cladding layer 110 having a relatively small thickness of 0.5 to 1 μm is processed to shape the ridges, and after the ridges are embedded in the current blocking layer 113, the compound semiconductor material of the second conductivity or the fourth cladding layer 117 having the same composition as that of the third cladding layer 110 is formed over the third cladding layer 110 and the current blocking layer 113, so that the sum of the film thicknesses of the third and fourth cladding layers 110 and 117 is the required Tp.

In this structure, the ridges can be shaped by means of the reaction rate-determining wet etching, and the high performance and high power reproducible semiconductor laser can be fabricated. The frequency of processing through MOCVD growth is, however, increased, and it is a tradeoff with reproducibility, or an alternative with the fourth embodiment as mentioned above.

In FIG. 10, only an inner structure of the chip is depicted, but similar to the Embodiment 1, COD can be inhibited by providing the window region that reasonably loses order due to Zn diffused in the vicinity of the facets. This embodiment can similarly be applied to the InGaAlP high power laser.

Although the embodiments of the present invention have been described, it is not intended that the invention should be limited to the precise form of them.

For example, the semiconductor laser in each embodiment is given simply by way of example, and any appropriate modifications of the semiconductor laser envisioned by any person skilled in the art should fall in the scope of the present invention without departing from the gist of the invention.

For instance, an optical guide layer may be interposed between the cladding layer and the active layer to guide light. In addition to that, various materials, conductivity types, impurity concentrations, processing methods, and the like that might be envisioned by a person having ordinary skills in the art for each component of the semiconductor laser, if providing the equivalent effects to those obtained from the present invention, should fall in the scope of the present invention.

As has been described in detail, a semiconductor laser in accordance with the present invention, while having a feature of restrained device resistance, satisfies various requirements such as optical throughput, angles of diverging light, kink level, temperature property, and the like depending upon its use and application like optical disk systems, and it also promises an increased productivity, which will give a lot of benefit in the Industry.

While the present invention has been disclosed in terms of the embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

What is claimed is:

1. A semiconductor laser comprising:
a cladding layer of a fist conductivity type;
an active layer provided over the cladding layer of the first conductivity type;
a cladding layer of a second conductivity type provided over the active layer, the cladding layer of a second conductivity type having a ridge shaped at its top, the ridge extending in parallel with a direction of laser resonance; and
a current blocking layer provided on opposite flanks of the ridge,
the cladding layers of the first and second conductivity types being made of semiconductor material having substantially the same composition, and
a thickness of the cladding layer of the first conductivity type is larger than a thickness of the cladding layer of the second conductivity type including the ridge.

2. A semiconductor laser according to claim 1, wherein the current blocking layer is made of semiconductor material having a wider band gap and a smaller refractive index than those of the cladding layers.

3. A semiconductor laser according to claim 1, wherein the cladding layer of the second conductivity type includes a second cladding layer below the ridge and a third cladding layer of which the ridge are shaped, and
a semiconductor layer having a composition different from those of the cladding layers is interposed between the second and third cladding layers.

4. A semiconductor laser according to claim 1, further comprising a burying cladding layer of the second conductivity type, the burying cladding layer covering the upper surfaces of the current blocking layer and the ridge, and
the burying cladding layer being made of semiconductor material having substantially the same composition as that of the cladding layer of the first conductivity type.

5. A semiconductor laser according to claim 4, wherein the thickness of the cladding layer of the first conductivity type is larger than a total thickness of the cladding layer of the second conductivity type including the ridge and the burying cladding layer.

6. A semiconductor laser according to claim 1, wherein the active layer includes a multi-layered structure having at least two semiconductor layers stacked one over another, and
the multi-layered structure of the active layer is selectively doped with Zinc (Zn) around its facet so that the multi-layered structure is disordered around the facet from which a laser beam is emitted.

7. A semiconductor laser according to claim 1, wherein the ridge is shaped by a reaction rate-determining etching.

8. A semiconductor laser according claim 1, wherein the cladding layers of the first and second conductivity types are respectively made of InGaAlP,
a sum of a thickness of the cladding layer of the first conductivity type and a thickness of the cladding layer of the second conductivity type along with a height of the ridge ranges from 2.5 μm to 3.5 μm, and
a thickness of the cladding layer of the second conductivity type without the height of the ridge ranges from 0.2 μm to 0.3 μm.

9. A semiconductor laser according to claim 8, wherein the ridge, when measured perpendicular to a direction of the laser resonance, has a width ranging 2.5 μm to 3.5 μm at its bottom.

10. A semiconductor laser according to claim 8, wherein the active layer includes a multiple quantum well structure having well layers and barrier layers alternately overlaid one after another,
three to five of the well layers are included in the multiple quantum well structure, and
each of the well layers has a thickness ranging from 4 nm to 7 nm and a compressive strain larger than 0% and equal to or smaller than 2% is applied thereto.

11. A semiconductor laser according to claim 1, wherein the cladding layers of the first and second conductivity types are respectively made of AlGaAs,
the sum of a thickness of the cladding layer of the first conductivity type and a thickness of the cladding layer of the second conductivity type along with a height of the ridge ranges from 4 μm to 6 μm,
the ridge has its opposite flanks inclined at an angle of 80 degrees or larger, and
the ridge, when measured perpendicular to the direction of the laser resonance, is shaped with a width ranging 2 μm to 3 μm at its bottom.

12. A semiconductor laser according to claim 1, wherein a facet from which a laser beam is emitted is coated with a film having a reflectivity of 15% or lower, and
an opposite end face is coated with a film having a reflectivity of 90% or higher.

13. A semiconductor laser according to claim 1, wherein the cladding layer of a fist conductivity type has a vertically uniform distribution of refractive index throughout its thickness, and the cladding layer of a second conductivity type has a vertically uniform distribution of refractive index throughout its thickness.

14. A semiconductor laser comprising:
a first cladding layer having a vertically uniform distribution of refractive index throughout its thickness;
an active layer provided over the first cladding layer; and
a second cladding layer provided over the active layer, the second cladding layer having a vertically uniform distribution of refractive index throughout its thickness, and having a ridge extending in parallel with a direction of laser resonance,
the first and second cladding layers being made of semiconductor material having substantially the same composition,
a thickness of the first cladding layer is larger than a thickness of the second cladding layer including the ridge, and
an asymmetrical distribution of light intensity being formed, the distribution showing its peak in a vicinity of the active layer and relatively rapidly dissipating in the second cladding layer while relatively gradually degrading in the first cladding layer.

15. A semiconductor laser according to claim 14, further comprising a current blocking layer provided on opposite flanks of the ridge.

16. A semiconductor laser according to claim 15, wherein the current blocking layer is made of semiconductor material having a wider band gap and a smaller refractive index than those of the cladding layers.

17. A semiconductor laser according to claim 14, wherein the active layer includes a multi-layered structure having at least two semiconductor layers stacked one over another, and
the multi-layered structure of the active layer is selectively doped with Zinc (Zn) around its facet so that the multi-layered structure is disordered around the facet from which a laser beam is emitted.

18. A semiconductor laser according to claim 14, wherein the ridge is shaped by a reaction rate-determining etching.

19. A method of manufacturing a semiconductor laser comprising:
forming a first cladding layer of a fist conductivity type, the first cladding layer having a vertically uniform distribution of refractive index throughout its thickness;
forming an active layer over the first cladding layer;
forming a second cladding layer of a second conductivity type over the active layer, the second cladding layer having a vertically uniform distribution of refractive index throughout its thickness, and the second cladding layer being made of semiconductor material having substantially the same composition as that of the first cladding layer;
forming an etching stop layer over the second cladding layer, the etching stop layer being made of semiconductor material of a different composition from that of the second cladding layer;
forming a third cladding layer over the etching stop layer, the third cladding layer having a vertically uniform distribution of refractive index throughout its thickness, the third cladding layer being made of semiconductor material of the second conductivity type and having substantially the same composition as that of the second cladding layer, and a sum of a thickness of the third cladding layer and a thickness of the second cladding layer is smaller than a thickness of the first cladding layer;
providing a mask in a striped pattern over the third cladding layer;
selectively etching the third cladding layer with a reaction rate-determining wet etchant to remove the third cladding layer without the mask thereon and shape ridge; and
providing a current blocking layer on the opposite flanks of the ridge.

20. A method of manufacturing a semiconductor laser according to claim 19, wherein the active layer includes a multi-layered structure having at least two semiconductor layers stacked one over another,
the method further comprising disordering the multi-layered structure of the active layer by selectively doping with Zinc (Zn) around its facet from which a laser beam is emitted.

21. A method of manufacturing a semiconductor laser according to claim 19, further comprising selectively etching the etching stop layer with a diffusion rate-determining wet etchant to remove the etching stop layer exposed at the opposite flanks of the ridge after shaping the ridge.
